(19) United States
(12) Patent Application Publication
(10) Pub. No.: US 2026/0372107 A1
(43) Pub. Date: Nov. 19, 2026

(54) SEMICONDUCTOR PACKAGE

(71) Applicant: Taiwan Semiconductor Manufacturing Company, Ltd., Hsinchu (TW)

(72) Inventors: Po-Yao CHUANG, Hsin-Chu (TW); Po-Hao TSAI, Zhongli City (TW); Shin-Puu JENG, Po-Shan Village (TW); Shuo-Mao CHEN, New Taipei City (TW); Ming-Chih YEW, Hsinchu City (TW)

(73) Assignee: Taiwan Semiconductor Manufacturing Company, Ltd., Hsinchu (TW)

(21) Appl. No.: 19/751,238

(22) Filed: Jul. 23, 2026

Related U.S. Application Data
(63) Continuation of application No. 17/688,647, filed on Mar. 7, 2022.
Application No. 17/688,647 is a division of application No. 16/284,630, filed on Feb. 25, 2019, now Pat. No. 11,270,953.
(60) Provisional application No. 62/725,675, filed on Aug. 31, 2018.

(51) Int. Cl. H10W 42/20; H05K 1/02; H10W 70/05; H10W 70/60; H10W 70/685; H10W 72/00; H10W 74/01; H10W 74/10; H10W 76/01; H10W 90/00; H10W 44/20; H10W 70/66; H10W 72/30

(52) U.S. Cl. CPC H10W 42/273; H05K 1/0218; H05K 1/0225; H10W 42/267; H10W 70/05; H10W 70/614; H10W 70/685; H10W 72/823; H10W 74/01; H10W 74/117; H10W 76/01; H10W 90/701; H10W 44/248; H10W 70/664; H10W 72/072; H10W 72/073; H10W 72/347; H10W 72/877; H10W 90/724

(57) ABSTRACT

A semiconductor package is provided. The semiconductor package includes a redistribution structure, a protective layer, a first semiconductor die, a plurality of conductive structures, a plurality of shielding elements, and a plurality of conductive elements. The protective layer is formed over the redistribution structure. The first semiconductor die is disposed in the protective layer. The conductive structures are formed in the protective layer. The conductive structures at least partially surround the first semiconductor die. The shielding elements at least partially vertically overlap the conductive structures. The conductive elements are in contact with the conductive structures and the shielding elements. Two of the conductive structures are separated from each other by a distance, and the distance is smaller than half a wavelength of an electromagnetic wave generated by the first semiconductor die.

### CROSS REFERENCE TO RELATED APPLICATIONS

This application is a Continuation of U.S. Patent Application Ser. No. 17/688,647, filed Mar. 7, 2022, which is a Divisional of U.S. Patent Application Ser. No. 16/284,630, filed Feb. 25, 2019, which claims the benefit of U.S. Provisional Application No. 62/725,675, filed Aug. 31, 2018, the entirety of which is incorporated by reference herein

### BACKGROUND OF THE INVENTION

### Field of the Invention

The present invention relates to devices and methods for forming a chip package.

### Description of the Related Art

Semiconductor devices are used in a variety of electronic applications, such as personal computers, cell phones, digital cameras, and other electronic equipment. The fabrication of the semiconductor devices involves sequentially depositing insulating or dielectric layers, conductive layers, and semiconductor layers over a semiconductor substrate, and patterning the various material layers using lithography and etching processes to form circuit components and elements on the semiconductor substrate.

The semiconductor industry continues to improve the integration density of various electronic components by continual reductions in minimum feature size, which allows more components to be integrated into a given area. The number of input and output connections is significantly increased. Smaller package structures, which utilize less area or have lower heights, are developed to package the semiconductor devices.

New packaging technologies have been developed to improve the density and functionality of semiconductor devices. These relatively new types of packaging technologies for semiconductor devices face manufacturing challenges.

### BRIEF SUMMARY OF THE INVENTION

According to some embodiments, a method for forming a chip package is provided. The method includes forming a plurality of conductive structures over a carrier substrate. The method also includes disposing a semiconductor die over the carrier substrate such that the conductive structures surround the semiconductor die. The method further includes disposing a shielding element over the semiconductor die and the conductive structures. The shielding element is electrically connected to the conductive structures.

According to some embodiments, a method for forming a chip package is provided. The method includes forming a plurality of conductive structures over a redistribution structure. The method also includes disposing a semiconductor die over the redistribution structure such that the conductive structures surround the semiconductor die. Two of the conductive structures are separated from each other by a distance, and the distance is smaller than half a wavelength of an electromagnetic wave generated by the semiconductor die.

According to some embodiments, a method for forming a chip package is provided. The method includes disposing a first semiconductor die and a second semiconductor die over a redistribution structure. The method also includes disposing a plurality of conductive structures over the redistribution structure. The conductive structures surround an area where the first semiconductor die is positioned, and the second semiconductor die is positioned outside of the area.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1F are cross-sectional views of various stages of a process for forming a chip package, in accordance with some embodiments.

FIGS. 2A-2E are cross-sectional views of various stages of a process for forming a chip package, in accordance with some embodiments.

FIG. 3 is a top view of an intermediate stage of a process for forming a chip package, in accordance with some embodiments.

FIG. 4 is a top view of an intermediate stage of a process for forming a chip package, in accordance with some embodiments.

FIG. 5 is a top view of an intermediate stage of a process for forming a chip package, in accordance with some embodiments.

FIG. 6 is a top view of an intermediate stage of a process for forming a chip package, in accordance with some embodiments.

FIG. 7 is a top view of an intermediate stage of a process for forming a chip package, in accordance with some embodiments.

FIGS. 8A-8C are cross-sectional views of various stages of a process for forming a chip package, in accordance with some embodiments.

FIG. 9 is a cross-sectional view of a chip package, in accordance with some embodiments.

FIG. 10 is a cross-sectional view of a chip package, in accordance with some embodiments.

FIG. 11 is a cross-sectional view of a chip package, in accordance with some embodiments.

FIG. 12 is a cross-sectional view of a chip package, in accordance with some embodiments.

FIG. 13 is a cross-sectional view of a chip package, in accordance with some embodiments.

FIG. 14 is a top view of a shielding element of a chip package, in accordance with some embodiments.

FIG. 15 is a top view of a shielding element of a chip package, in accordance with some embodiments.

### DETAILED DESCRIPTION OF THE INVENTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element or feature as illustrated in the figures. The spatially relative terms are intended to encompass different orientations of the device in use or operation in addition to the orientation depicted in the figures. The apparatus may be otherwise oriented and the spatially relative descriptors used herein may likewise be interpreted accordingly.

Embodiments of the disclosure may be applied in 3D packaging or 3D IC devices. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

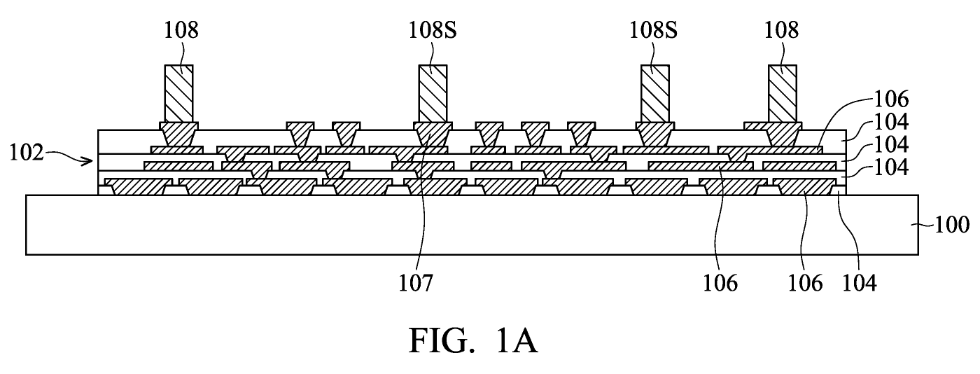

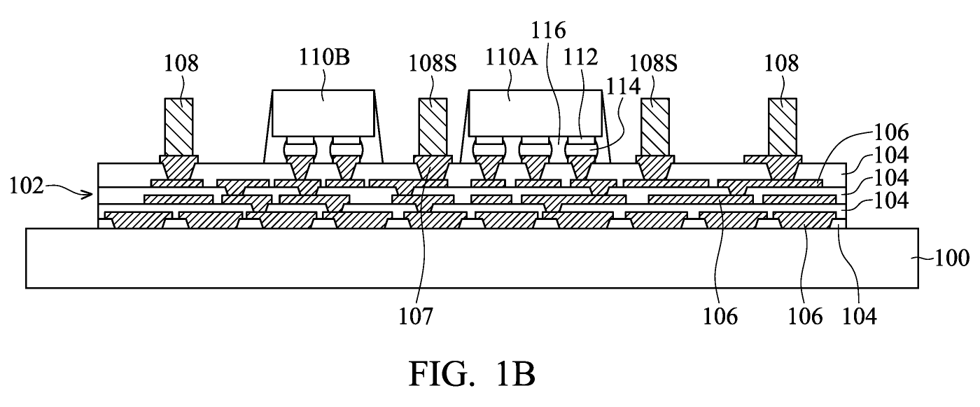

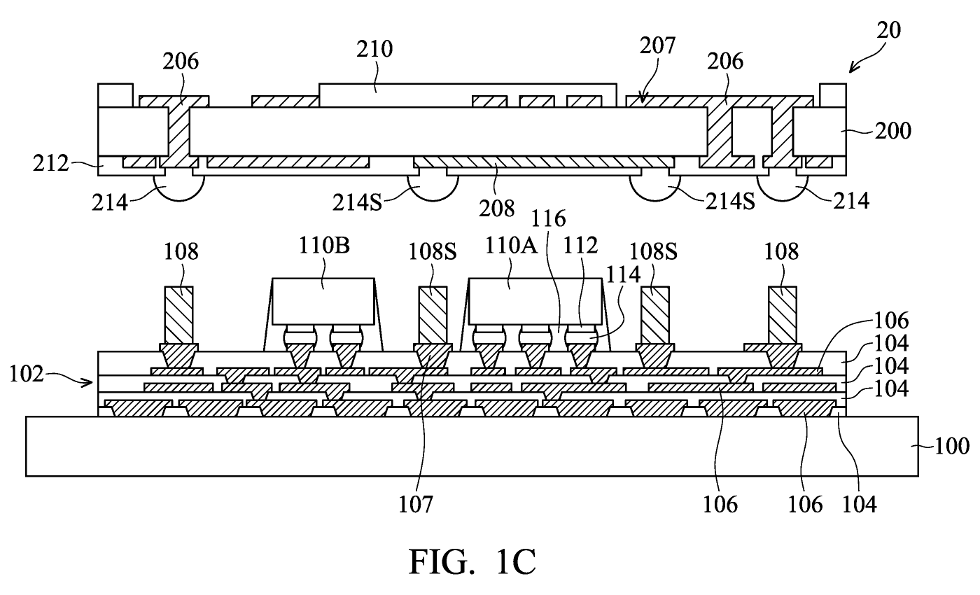

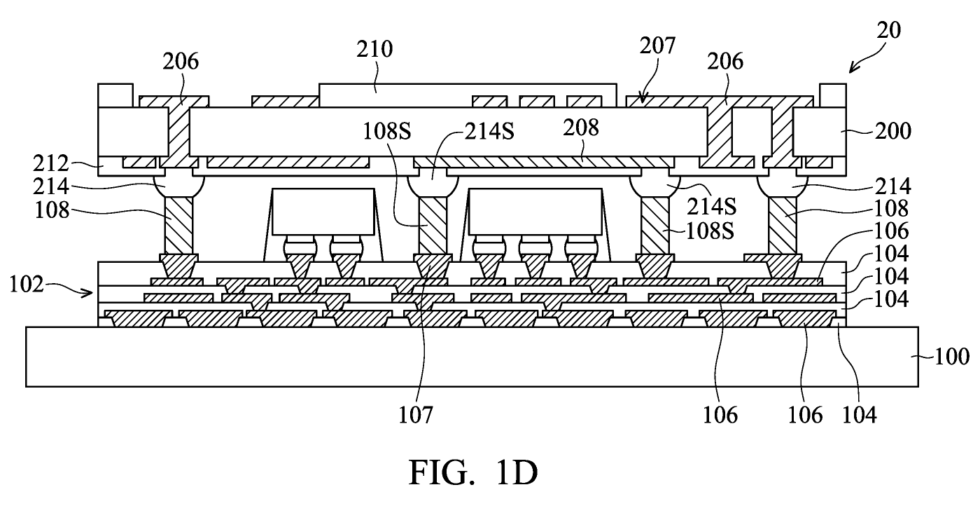

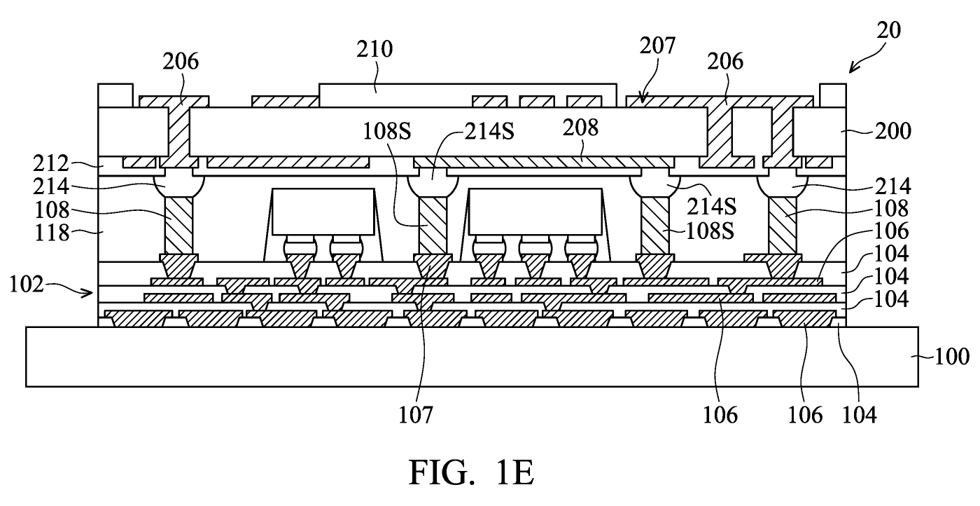

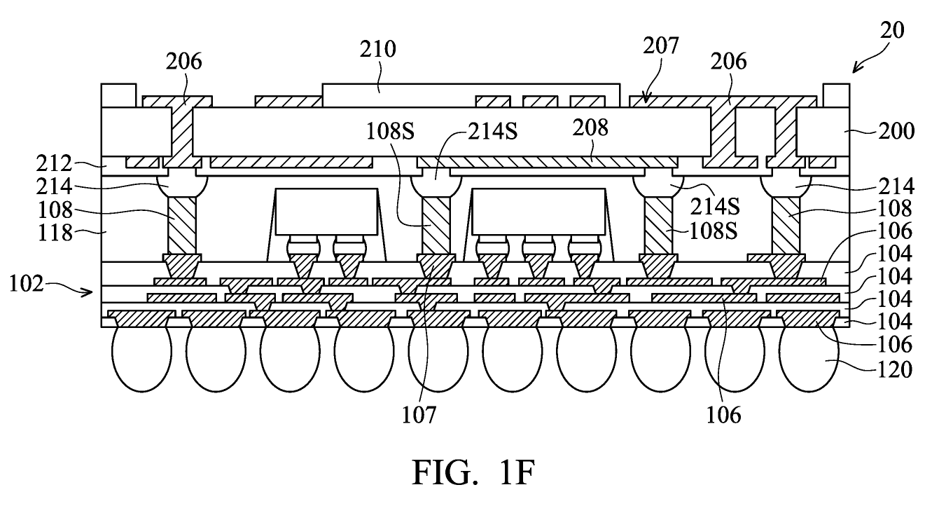

FIGS. 1A-1F are cross-sectional views of various stages of a process for forming a chip package, in accordance with some embodiments. As shown in FIG. 1A, an interconnection structure 102 is formed over the carrier substrate 100, in accordance with some embodiments. The interconnection structure 102 may be used as a redistribution structure for routing. The interconnection structure 102 includes multiple insulating layers 104 and multiple conductive features 106, as shown in FIG. 1A. The conductive features 106 may include conductive lines, conductive vias, and/or conductive pads. The interconnection structure 102 also includes conductive features 107 that are used to hold or receive other elements such as conductive pillars or semiconductor dies.

In some embodiments, some of the conductive features 107 are exposed at or protrude from the topmost surface of the insulating layers 104. The exposed or protruding conductive features 107 may serve as bonding pads where conductive bumps and/or conductive pillars will be formed later.

The insulating layers 104 may be made of or include one or more polymer materials. The polymer material may include polybenzoxazole , polyimide , one or more other suitable polymer materials, or a combination thereof. In some embodiments, the polymer material is photosensitive. In some embodiments, some or all of the insulating layers 104 are made of or include dielectric materials other than polymer materials. The dielectric material may include silicon oxide, silicon carbide, silicon nitride, silicon oxynitride, one or more other suitable materials, or a combination thereof.

The conductive features 106 may include conductive lines providing electrical connection in horizontal directions and conductive vias providing electrical connection in vertical directions. The conductive features 106 may be made of or include copper, aluminum, gold, cobalt, titanium, graphene, one or more other suitable conductive materials, or a combination thereof.

The formation of the interconnection structure 102 may involve multiple deposition or coating processes, multiple patterning processes, and/or multiple planarization processes.

The deposition or coating processes may be used to form insulating layers and/or conductive layers. The deposition or coating processes may include a spin coating process, an electroplating process, an electroless process, a chemical vapor deposition process, a physical vapor deposition process, an atomic layer deposition process, one or more other applicable processes, or a combination thereof.

The patterning processes may be used to pattern the formed insulating layers and/or the formed conductive layers. The patterning processes may include a photolithography process, an energy beam drilling process , an etching process, a mechanical drilling process, one or more other applicable processes, or a combination thereof.

The planarization processes may be used to provide the formed insulating layers and/or the formed conductive layers with planar top surfaces to facilitate subsequent processes. The planarization processes may include a mechanical grinding process, a chemical mechanical polishing process, one or more other applicable processes, or a combination thereof.

However, many variations and/or modifications can be made to embodiments of the disclosure. In some other embodiments, the interconnection structure 102 is not formed.

Afterwards, conductive structures 108 and 108S are formed over some of the conductive features 107, as shown in FIG. 1A in accordance with some embodiments. In some embodiments, the conductive structures 108 are used for signal transmission. In some embodiments, the conductive structures 108S are used as a shielding structure capable of preventing electromagnetic interference caused by a semiconductor die that will be disposed later.

In some embodiments, the conductive structures 108 and 108S are conductive pillars. In some embodiments, the conductive structures 108 and 108S have substantially straight sidewalls. The sidewalls of the conductive structures 108 and 108S may be substantially perpendicular to the top surface of the carrier substrate 100. The conductive structures 108 and 108S may be made of or include copper, aluminum, titanium, cobalt, gold, tin-containing alloys, one or more other suitable materials, or a combination thereof.

The conductive structures 108 and 108S may be formed using an electroplating process, an electroless plating process, a PVD process, a CVD process, one or more other applicable processes, or a combination thereof. In some other embodiments, the conductive structures 108 and 108S are picked and placed onto the exposed conductive features 107. Tin-containing solder elements may be used to affix the conductive structures 108 and 108S. In some embodiments, the conductive structures 108 and 108S are simultaneously formed. In some other embodiments, the conductive structures 108 and 108S are separately formed. For example, the conductive structures 108 are formed before the conductive structures 108S. Alternatively, the conductive structures 108S are formed before the conductive structures 108.

As shown in FIG. 1B, semiconductor device such as a semiconductor dies 110A and 110B are disposed over the carrier substrate 100, in accordance with some embodiments. The semiconductor die 110B is disposed outside of an area that is surrounded by the conductive structures 108S, as shown in FIG. 1B.

In some embodiments, the semiconductor dies 110A and 110B are disposed onto some of the exposed conductive features 107. The semiconductor dies 110A and 110B may be a system-on-chip chip. In some other embodiments, the element 110A or 110B is a system on integrated circuit device that includes two or more chips with integrated function. In these cases, the reference number “110A or 110B” is used to designate a semiconductor device. The semiconductor device may include one die, multiple dies, or system-on-integrated-circuit chip device. For example, one or two of the elements 110A and 110B include a stack of multiple semiconductor dies.

In some embodiments, the semiconductor die 110A includes radio-frequency integrated circuits such as radio-frequency front end modules. The operation frequency of the semiconductor die 110A is in the radio-frequency range. An electromagnetic wave having the wavelength corresponding to the operation frequency may be generated by the semiconductor die 110A during operation.

For example, the operation frequency of the semiconductor die 110A may be about 28 GHz. In these cases, electromagnetic wave having a wavelength of about 10.7 mm may be generated by the semiconductor die 110A during operation. For example, the electromagnetic wave may be transmitted through the protective substrate 20. In some cases, the generated electromagnetic wave may negatively affect the operation of nearby device elements. In some embodiments, shielding structures and/or shielding elements are formed later to prevent the generated electromagnetic wave from reaching nearby device elements and affecting the operation of the nearby device elements.

In some embodiments, the semiconductor die 110B includes low-noise amplifier modules, low-loss filter modules, power amplifier modules, baseband modules, power management integrated circuit , memory modules, micro-electromechanical system modules, nano-electromechanical systems modules, one or more other suitable circuits, or a combination thereof. In some embodiments, the semiconductor die 110B does not include any radio-frequency integrated circuit.

In some embodiments, the semiconductor dies 110A and 110B are disposed over the interconnection structure 102 formed over the carrier substrate 100. In some embodiments, the semiconductor dies 110A and 110B are bonded to some of the conductive features 107 of the interconnection structure 102 through bonding structures 114. The bonding structures 114 may physically and electrically connect some of the conductive features 107 and conductive features 112 of the semiconductor dies 110A and 110B. The conductive features 112 of the semiconductor dies 110A and 110B may include conductive pads, conductive pillars, conductive traces, or the like.

In some embodiments, the bonding structures 114 are or include solder bumps such as tin-containing solder bumps. The tin-containing solder bumps may further include copper, silver, gold, aluminum, lead, one or more other suitable materials, or a combination thereof. In some embodiments, the tin-containing solder bump is lead free. The formation of the bonding structures 114 may involve one or more reflow processes and /or one or more plating processes.

As shown in FIG. 1B, underfill elements 116 are formed to protect the bonding structures 114, in accordance with some embodiments. The underfill elements 116 are made of or include one or more polymer materials. The underfill elements 116 may include an epoxy-based resin. In some embodiments, the underfill elements 116 further include fillers dispersed in the epoxy-based resin. In some embodiments, the formation of the underfill elements 116 involves an injecting process, a dispensing process, a film lamination process, an application process, one or more other applicable processes, or a combination thereof. In some embodiments, a thermal curing process is then used to complete the formation of the underfill elements 116.

As shown in FIG. 1C, a protective substrate 20 is provided or received and is ready to be bonded onto the conductive structures 108 and 108S, in accordance with some embodiments. In some embodiments, the protective substrate 20 includes a board 200 and a shielding element 208. In some embodiments, the protective substrate 20 also includes conductive elements 214 and 214S. In some embodiments, the protective substrate 20 includes antenna elements, main patch elements, parasitic patch elements, ground elements, one or more other suitable elements, or a combination thereof.

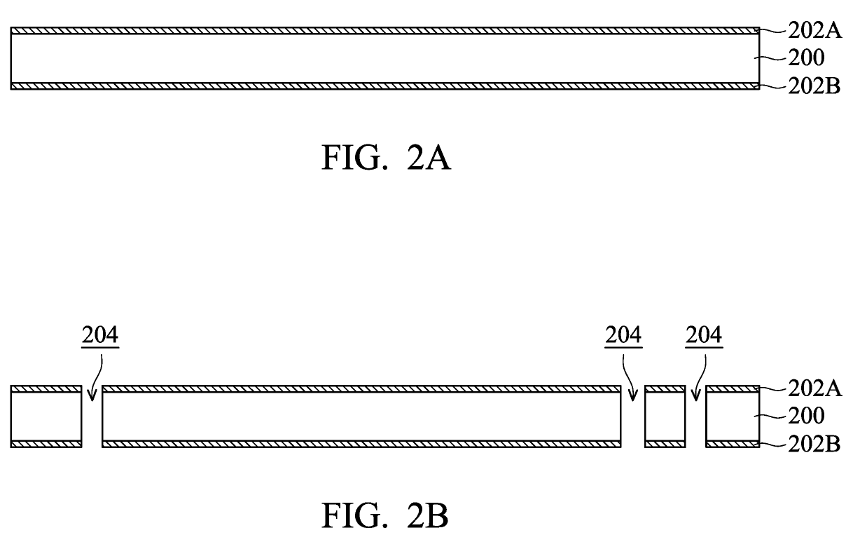

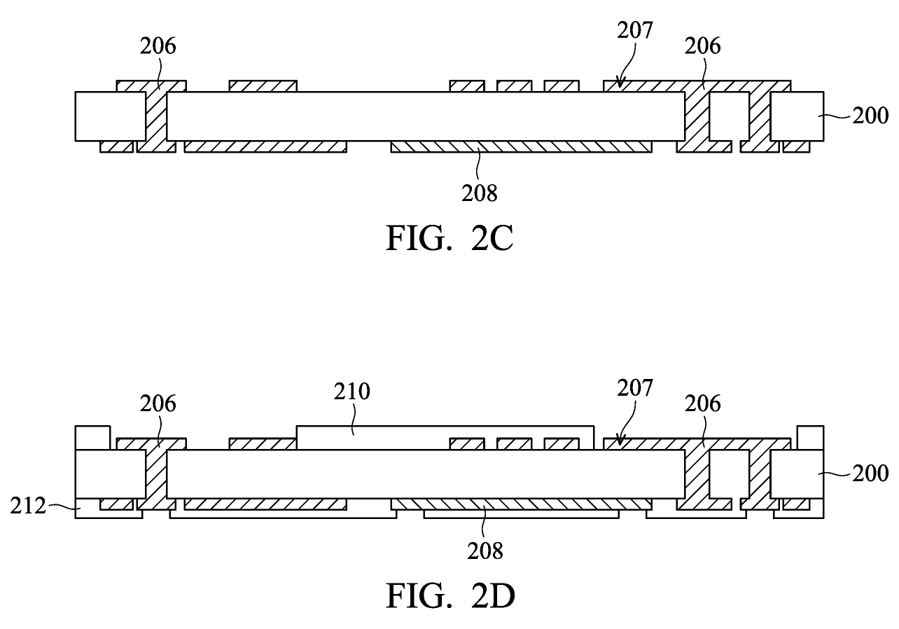

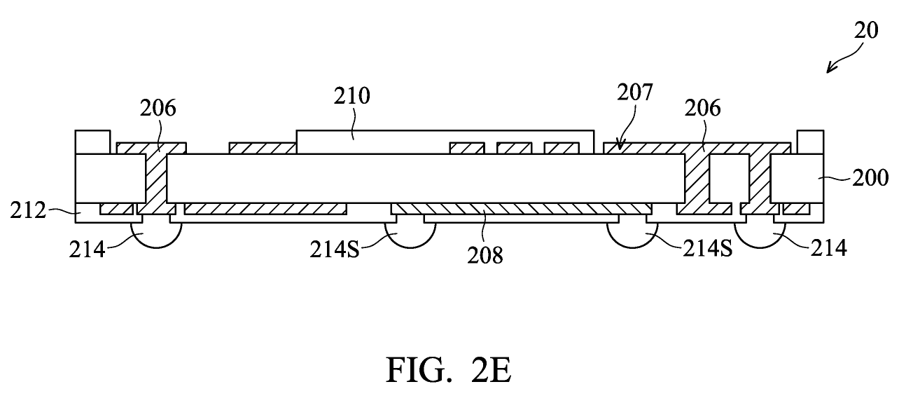

FIGS. 2A-2E are cross-sectional views of various stages of a process for forming a chip package, in accordance with some embodiments. In some embodiments, the protective substrate 20 in FIG. 1C is formed using the process illustrated in FIGS. 2A-2E.

As shown in FIG. 2A, conductive films 202A and 202B are formed over opposite surfaces of the board 200, in accordance with some embodiments. The conductive films 202A and 202B may be used to assist in a subsequent electroplating process. The board 200 may be made of or include a polymer material, a ceramic material, a metal material, a semiconductor material, one or more other suitable materials, or a combination thereof For example, the board 200 includes resin, prepreg, glass, and/or ceramic.

The conductive films 202A and 202B may be made of or include aluminum, copper, cobalt, gold, titanium, one or more other suitable materials, or a combination thereof. The conductive films 202A and 202B may be formed using a thermal compression process, a PVD process, a CVD process, a lamination process, a printing process, one or more other application processes, or a combination thereof.

However, embodiments of the disclosure are not limited thereto. In some other embodiments, the conductive films 202A and 202B are not formed.

As shown in FIG. 2B, the conductive films 202A and 202B and the board 200 are partially removed to form openings 204, in accordance with some embodiments. In some embodiments, the openings 204 completely penetrate through the board 200 and the conductive films 202A and 202B. The openings 204 may be formed using an energy beam drilling process, a mechanical drilling process, photolithography and etching processes, one or more other applicable processes, or a combination thereof. The energy beam drilling process may include a laser drilling process, an ion beam drilling process, an electron beam drilling process, a plasma beam drilling process, one or more other applicable processes, or a combination thereof.

Afterwards, a seed layer is deposited over the structure shown in FIG. 2B in accordance with some embodiments. The seed layer extends over the conductive films 202A and 202B. The seed layer further extends over sidewalls of the opening 204. Afterwards, patterned photoresist layers are formed on the seed layer. The patterned photoresist layers have openings that partially expose the seed layer and define patterns of conductive features to be formed on the board 200 later. Then, one or more conductive materials are electroplated on the portions of the seed layer not covered by the patterned photoresist layers. Afterwards, the patterned photoresist layers are removed. One or more etching processes are used to remove the portions of the seed layer originally covered by the patterned photoresist layers. The portions of the conductive films 202A and 202B originally covered by the patterned photoresist layers are also removed during the one or more etching processes.

As a result, the board 200 is partially exposed, as shown in FIG. 2C, in accordance with some embodiments. The remaining portions of the electroplated conductive material, the remaining seed layer, and the remaining conductive films 202A and 202B together form conductive features 206 with desired patterns. Some of the conductive features 206 penetrate through the board 200 to provide electrical connections between elements to be positioned on the opposite surfaces of the board.

In some embodiments, some of the conductive features 206 together form one antenna element 207, as shown in FIG. 2C. The pattern of the antenna element 207 may be fine-tuned to provide desired functions. In some embodiments, the antenna element 207 is a patch antenna that is used to receive and/or transmit electromagnetic signals in normal direction. In some other embodiments, the antenna element 207 is an end-fire antenna that is used to receive and/or transmit electromagnetic signals in side direction. In some embodiments, multiple antenna elements with different functions are formed over the board 200.

As shown in FIG. 2C, a shielding element 208 is formed over the bottom surface of the board 200, in accordance with some embodiments. In some embodiments, one or more of the conductive features 206 form the shielding element 208. In these cases, the antenna element 207 and the shielding element 208 are formed from patterning the same conductive material layer. The antenna element 207 and the shielding element 208 are made of the same material. In some other embodiments, the shielding element 208 and the conductive features 206 are formed using different processes. In some embodiments, the shielding element 208 and the antenna element 207 are made of different materials.

As shown in FIG. 2D, protective layers 210 and 212 are formed over the opposite surfaces of the board 200, in accordance with some embodiments. The protective layers 210 and 212 may be made of or include epoxy-based resin, polyimide, polybenzoxazole, one or more other suitable materials, or a combination thereof. The protective layers 210 and 212 have multiple openings that partially expose the conductive features 206. For example, the antenna element 207 and the shielding element 208 are partially exposed, as shown in FIG. 2D. The formation of the protective layers 210 and 212 may involve a coating process and a photolithography process. The coating process may include a spin coating process, a spray coating process, a lamination process, one or more other applicable processes, or a combination thereof.

As shown in FIG. 2E, conductive bumps 214 are formed over some of the conductive features 206, in accordance with some embodiments. In some embodiments, conductive bumps 214S are formed over the exposed portions of the shielding element 208, as shown in FIG. 2E. In some embodiments, the conductive bumps 214 and 214S are made of the same material. In some embodiments, the conductive bumps 214 and 214S are tin-containing solder elements. The tin-containing solder elements may further include copper, silver, gold, aluminum, lead, one or more other suitable materials, or a combination thereof. In some embodiments, the tin-containing solder elements are lead free. The formation of the conductive bumps 214 and 214S may involve one or more plating processes and/or one or more reflow processes. Afterwards, a singulation process may be carried out to saw through the structure. As a result, multiple substrates 20 are formed. In FIG. 2E, one of the substrates 20 is shown.

Referring back to FIG. 1C, the protective substrate 20 is positioned to allow the conductive elements 214 to be substantially aligned with the conductive structures 108, in accordance with some embodiments. The protective substrate 20 is also positioned to allow the conductive elements 214S to be substantially aligned with the conductive structures 108S. As mentioned above, in some embodiments, the conductive elements 214 and 214S are tin-containing solder elements which may facilitate a subsequent bonding process.

As shown in FIG. 1D, the protective substrate 20 is bonded to the conductive structures 108 and 108S, in accordance with some embodiments. In some embodiments, the protective substrate 20 is bonded to the conductive structures 108 and 108S through the conductive bumps 214 and 214S. As mentioned above, in some embodiments, the conductive bumps 214 and 214S are tin-containing solder elements. A reflow process may be used to bond the conductive bumps 214 and 214S to the conductive structures 108 and 108S, respectively. In some embodiments, after the protective substrate 20 is bonded onto the conductive structures 214 and 214S, the shielding element 208 is also disposed over the semiconductor die 110A. The shielding element 208 is electrically connected to the conductive structures 108S through the conductive bumps 214S.

The conductive structures 108S and the shielding element 208 may be used to prevent the electromagnetic wave generated by the semiconductor die 110A from affecting the operation of nearby device elements, such as the semiconductor die 110B or another nearby package. In some other cases where the conductive structures 108S or the shielding element 208 are not formed, the electromagnetic wave generated by the semiconductor die 110A may negatively affect the operation of the semiconductor die 110B or the operation of another nearby device elements.

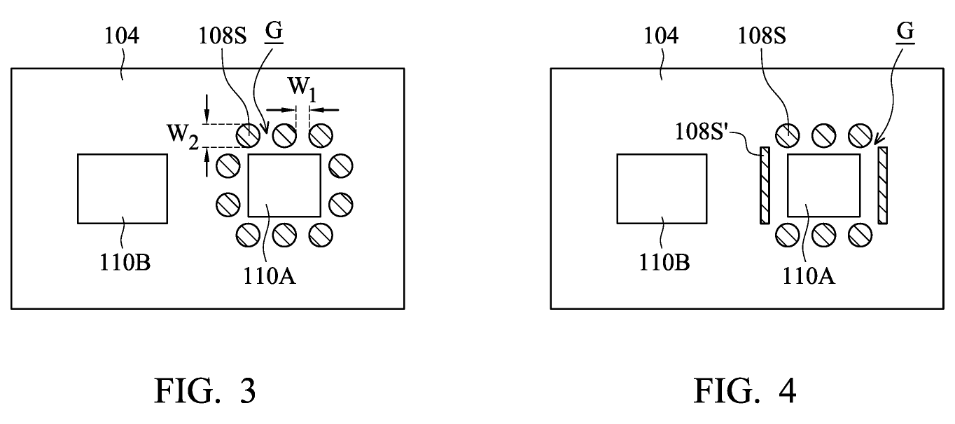

FIG. 3 is a top view of an intermediate stage of a process for forming a chip package, in accordance with some embodiments. In some embodiments, FIG. 3 shows the top view of the structure shown in FIG. 1B. For simplicity and clarity, only the shielding structure, the topmost insulating layer 104, and the semiconductor dies 110A and 110B are illustrated.

As shown in FIG. 3, the conductive structures 108S surround or encircle a space where the semiconductor die 110A is positioned, in accordance with some embodiments. The semiconductor die 110B is disposed outside of an area that is surrounded by the conductive structures 108S. In some embodiments, the top view of each of the conductive structures 108S has a circular profile. The conductive structures 108S together form a shielding structure. The shielding structure has multiple openings G that expose the space containing the semiconductor die 110A. Therefore, during a subsequent formation process of a protective layer, a portion of the protective layer could penetrate through the openings G to surround and protect the semiconductor die 110A.

In some embodiments, two nearby conductive structures 108S are separated from each other by a distance W1, as shown in FIG. 3. The distance W1 may be in a range from about 10 µm to half the wavelength of the electromagnetic wave generated by the semiconductor die 110A. Each of the conductive structures 108S has a width W2, as shown in FIG. 3. In some embodiments, the width W2 is in a range from about 5 µm to about ten times the distance W1 to ensure sufficient shielding efficiency.

In some cases, if the distance W1 is smaller than about 10 µm, the subsequently formed protective layer might not be able to penetrate through the openings to protect the semiconductor die 110A. Alternatively, the subsequently formed protective layer might not be able to completely surround and protect the semiconductor die 110A. The reliability and quality of the chip package may be negatively affected.

In some other cases, if the distance W1 is greater than half the wavelength of the electromagnetic wave generated by the semiconductor die 110A, the shielding efficiency may not be sufficient. As a result, the electromagnetic wave generated by the semiconductor die 110A during operation may not be well shielded and may reach the nearby device elements to negatively affect the operation.

For example, the operation frequency of the semiconductor die 110A may be about 28 GHz. In these cases, electromagnetic wave having a wavelength of about 10.7 mm may be generated by the semiconductor die 110A during operation. In these cases, half the wavelength of the electromagnetic wave generated by the semiconductor die 110A is about 5.35 mm. In some embodiments, the distance W1 is designed to be in a range from about 10 µm to about 5.35 mm to ensure sufficient shielding efficiency and to ensure sufficient protection of the semiconductor die 110A. In some embodiments, the width W2 is designed to be in a range from about 5 µm to about 53.5 mm.

However, embodiments of the disclosure are not limited thereto. Many variations and/or modifications can be made to embodiments of the disclosure. The top views of different conductive structures may have different shapes.

FIG. 4 is a top view of an intermediate stage of a process for forming a chip package, in accordance with some embodiments. In some embodiments, FIG. 4 shows the top view of the structure shown in FIG. 1B. For simplicity and clarity, only the shielding structure, the topmost insulating layer 104, and the semiconductor dies 110A and 110B are illustrated.

As shown in FIG. 4, the semiconductor die 110A is surrounded by not only the conductive structures 108S but also the conductive walls 108S’, in accordance with some embodiments. In some embodiments, a lateral extending direction of the conductive walls 108S’ is substantially parallel to a lateral extending direction of the side of the semiconductor die 110A. The conductive structures 108S and the conductive walls 108S’ together function as a shielding structure.

The shielding structure has multiple openings G that expose the space containing the semiconductor die 110A. Therefore, during a subsequent formation process of a protective layer, a portion of the protective layer could penetrate through the openings G to surround and protect the semiconductor die 110A. In some embodiments, the distance between any nearby conductive structures 108S and/or conductive walls 108S’ is in a range from about 10 µm to half the wavelength of the electromagnetic wave generated by the semiconductor die 110A.

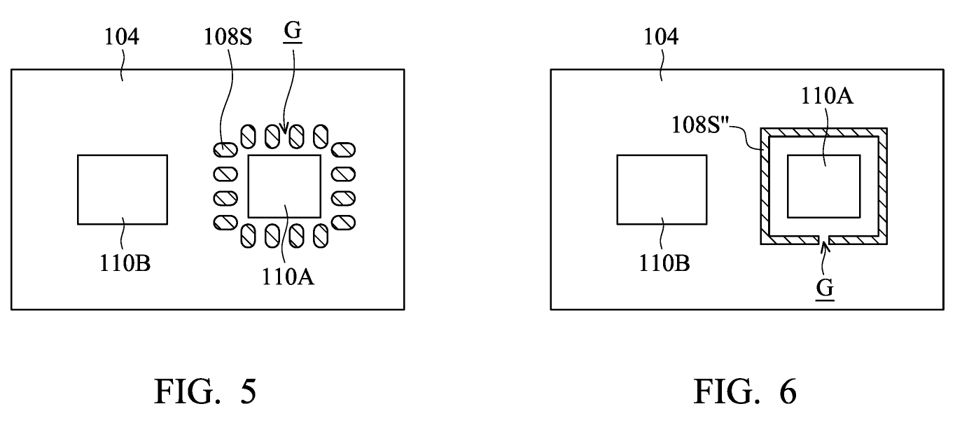

Many variations and/or modifications can be made to embodiments of the disclosure. FIG. 5 is a top view of an intermediate stage of a process for forming a chip package, in accordance with some embodiments. In some embodiments, FIG. 5 shows the top view of the structure shown in FIG. 1B. For simplicity and clarity, only the shielding structure, the topmost insulating layer 104, and the semiconductor dies 110A and 110B are illustrated.

In some embodiments, the top view of each of the conductive structures 108S has an oval profile, as shown in FIG. 5. The conductive structures 108S together form a shielding structure. The shielding structure has multiple openings G that expose the space containing the semiconductor die 110A. Therefore, during a subsequent formation process of a protective layer, a portion of the protective layer could penetrate through the openings G to surround and protect the semiconductor die 110A. In some embodiments, the distance between any nearby conductive structures 108S and/or conductive walls 108S’ is in a range from about 10 µm to half the wavelength of the electromagnetic wave generated by the semiconductor die 110A.

Many variations and/or modifications can be made to embodiments of the disclosure. FIG. 6 is a top view of an intermediate stage of a process for forming a chip package, in accordance with some embodiments. In some embodiments, FIG. 6 shows the top view of the structure shown in FIG. 1B. For simplicity and clarity, only the shielding structure, the topmost insulating layer 104, and the semiconductor dies 110A and 110B are illustrated.

In some embodiments, the semiconductor die 110A is surrounded by a single conductive wall 108S” that functions as a shielding structure. The shielding structure has an openings G that expose the space containing the semiconductor die 110A. Therefore, during a subsequent formation process of a protective layer, a portion of the protective layer could penetrate through the openings G to surround and protect the semiconductor die 110A. In some embodiments, the width of the opening G is in a range from about 10 µm to half the wavelength of the electromagnetic wave generated by the semiconductor die 110A.

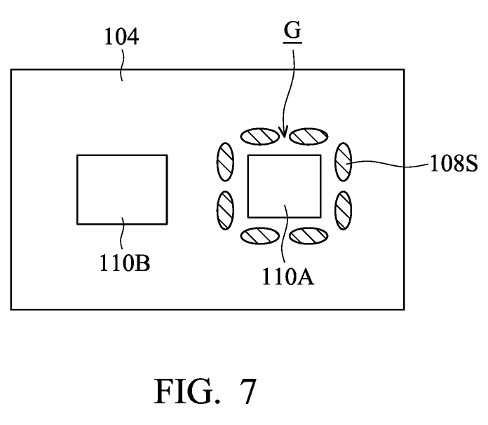

Many variations and/or modifications can be made to embodiments of the disclosure. FIG. 7 is a top view of an intermediate stage of a process for forming a chip package, in accordance with some embodiments. In some embodiments, FIG. 7 shows the top view of the structure shown in FIG. 1B. For simplicity and clarity, only the shielding structure, the topmost insulating layer 104, and the semiconductor dies 110A and 110B are illustrated.

In some embodiments, the top view of each of the conductive structures 108S has an oval profile, as shown in FIG. 7. In some embodiments, the long axis of one or each of the conductive structures 108S extends along a direction that is substantially parallel to the extending direction of the corresponding side of the semiconductor die 110A, as shown in FIG. 7.

The conductive structures 108S together form a shielding structure. The shielding structure has multiple openings G that expose the space containing the semiconductor die 110A. Therefore, during a subsequent formation process of a protective layer, a portion of the protective layer could penetrate through the openings G to surround and protect the semiconductor die 110A. In some embodiments, a distance between any nearby conductive structures 108S and/or conductive walls 108S’ is in a range from about 10 µm to half the wavelength of the electromagnetic wave generated by the semiconductor die 110A.

In some embodiments, as mentioned above, the shielding structure and the shielding element 208 are electrically connected to each other. Therefore, the shielding structure and the shielding element 208 may together reduce or prevent the electromagnetic interference effect caused by the semiconductor die 110A. Many variations and/or modifications can be made to the shielding element 208, in accordance with some embodiments. For example, the top view of the shielding element 208 has many variations.

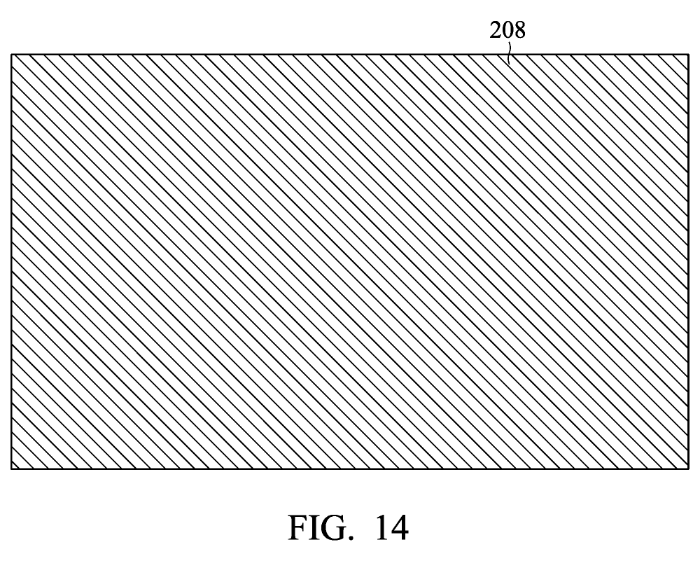

FIG. 14 is a top view of a shielding element of a chip package, in accordance with some embodiments. In some embodiments, FIG. 14 shows the top view of the shielding element 208 shown in FIG. 1D. In some embodiments, the shielding element 208 is a conductive plate. In some embodiments, the conductive plate has no opening or through-hole. In some embodiments, the shielding element 208 covers the shielding structure and the semiconductor die 110A.

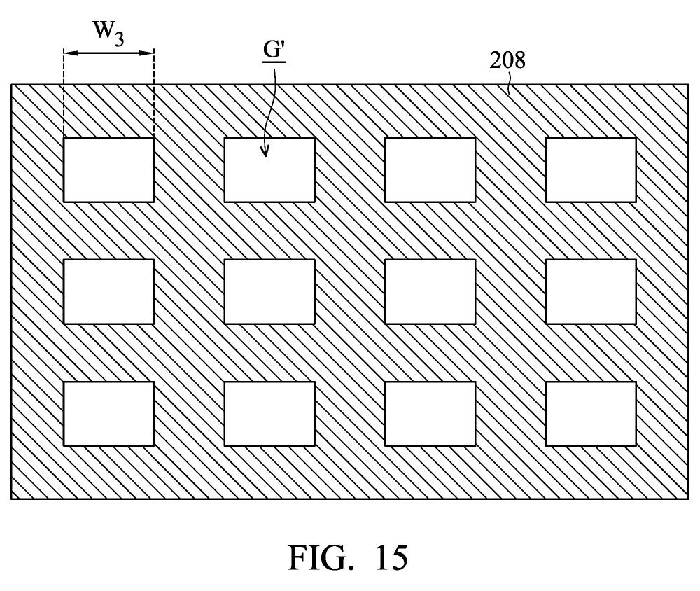

Many variations and/or modifications can be made to embodiments of the disclosure. FIG. 15 is a top view of a shielding element of a chip package, in accordance with some embodiments. In some embodiments, the shielding element 208 is a conductive mesh with many through-holes G’. In some embodiments, each of the through-holes G’ is designed to have a width W3 that is in a range from about 10 µm to half the wavelength of the electromagnetic wave generated by the semiconductor die 110A. Therefore, the shielding efficiency of the shielding element 208 is ensured.

In some other embodiments, the shielding element 208 includes a combination of a conductive plate and a conductive mesh. For example, a portion of the shielding element 208 is a conductive plate without through-holes G’, and another portion of the shielding element 208 is a conductive mesh with through-holes G’.

Referring to FIG. 1E, a protective layer 118 is formed to surround the semiconductor dies 110A and 110B and the conductive structures 108S and 108, in accordance with some embodiments. In some embodiments, the protective layer 118 penetrates through the openings G between the conductive structures 108S to surround the semiconductor die 110A. In some embodiments, the protective layer 118 is in direct contact with the conductive structures 108 and 108S. In some embodiments, the protective layer 118 is in direct contact with the semiconductor dies 110A and 110B. In some embodiments, a portion of the protective layer 118 is between the semiconductor die 110A and the shielding element 208.

In some embodiments, the material of the protective layer 118 is different from that of the board 200. In some embodiments, the protective layer 118 has a greater dielectric constant than that of the board 200. In some embodiments, the protective layer 118 has a greater dissipation factor than that of the board 200.

In some embodiments, the protective layer 118 is made of or includes a molding compound material. The molding compound material may include a polymer material, such as an epoxy-based resin with fillers dispersed therein. In some embodiments, a liquid molding compound material is introduced or injected between the protective substrate 20 and the carrier substrate 100. The liquid molding compound material may flow into the openings G to encapsulate the semiconductor die 110A. A thermal process is then used to cure the liquid molding compound material and to transform it into the protective layer 118.

As shown in FIG. 1F, the carrier substrate 100 is removed, and conductive bumps 120 are formed, in accordance with some embodiments. In some embodiments, the conductive bumps 120 are or include solder bumps such as tin-containing solder bumps. The tin-containing solder bumps may further include copper, silver, gold, aluminum, lead, one or more other suitable materials, or a combination thereof. In some embodiments, the tin-containing solder bump is lead free. In some embodiments, solder balls are disposed onto the exposed conductive features 106 after the removal of the carrier substrate 100. A reflow process is then carrier out to melt the solder balls into the conductive bumps 120. In some other embodiments, under bump metallization elements are formed over the exposed conductive features 106 before the solder balls are disposed. In some other embodiments, solder elements are electroplated onto the exposed conductive features 106. Afterwards, a reflow process is used to melt the solder element to form the conductive bumps 120. In some embodiments, a singulation process is then carrier out to saw through the formed structure. As a result, multiple separate chip packages are formed. In FIG. 1F, one of the chip packages is shown.

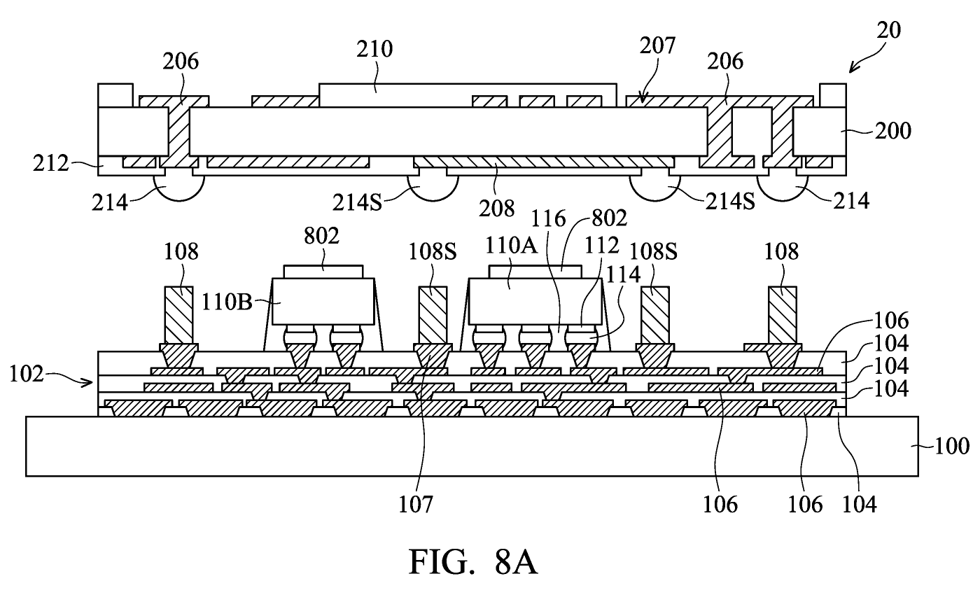

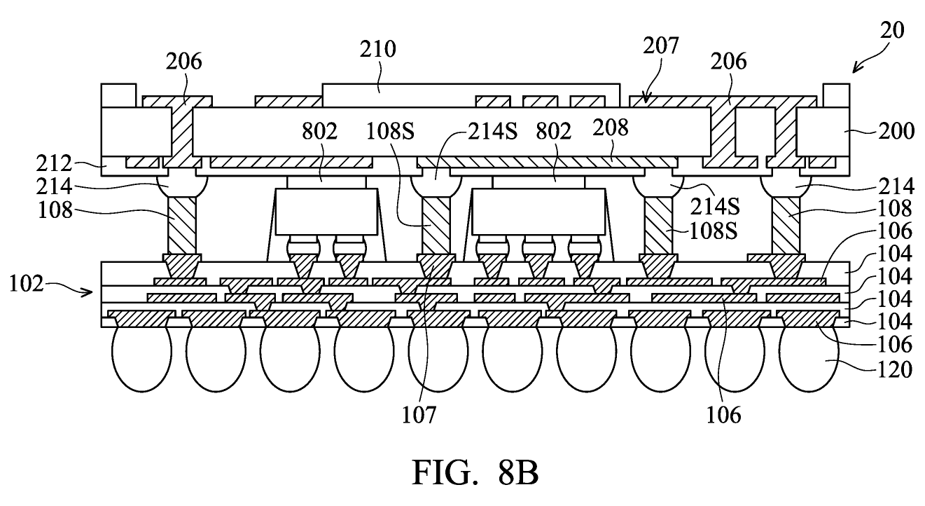

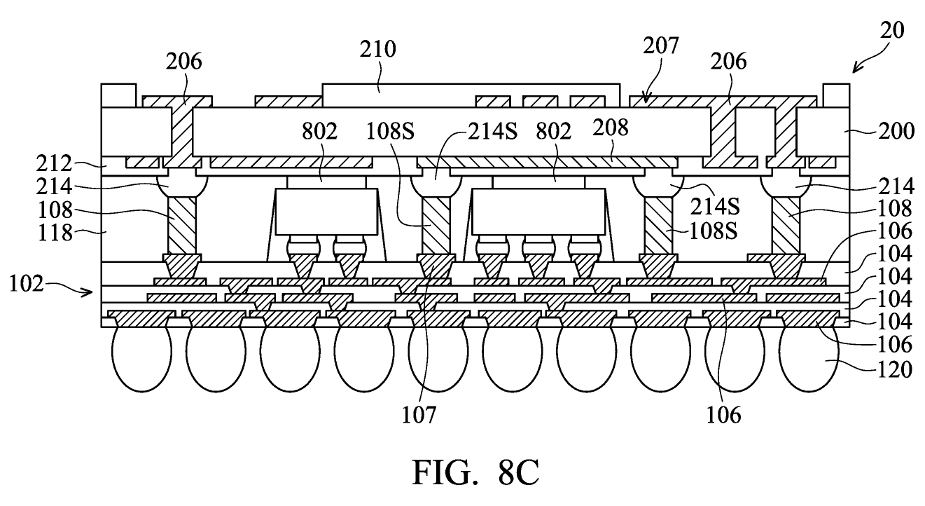

Many variations and/or modifications can be made to embodiments of the disclosure. FIGS. 8A-8C are cross-sectional views of various stages of a process for forming a chip package, in accordance with some embodiments. As shown in FIG. 8A, a structure similar to the structure shown in FIG. 1C is provided or formed, in accordance with some embodiments.

In some embodiments, adhesive elements 802 are formed over the semiconductor dies 110A and 110B before the protective substrate 20 is bonded to the conductive structures 108 and 108S, as shown in FIG. 8A. The adhesive elements 802 may include adhesive tapes, adhesive glue, or other suitable elements.

As shown in FIG. 8B, the protective substrate 20 is bonded to the conductive structures 108 and 108S, in accordance with some embodiments. In some embodiments, the protective substrate 20 is bonded to the conductive structures 108 and 108S through the conductive bumps 214 and 214S. The adhesive elements 802 may assist in the bonding process to prevent misalignment and/or undesired displacement.

Afterwards, the processes the same as or similar to those illustrated in FIGS. 1E and 1F are used to form a chip package, as shown in FIG. 8C in accordance with some embodiments.

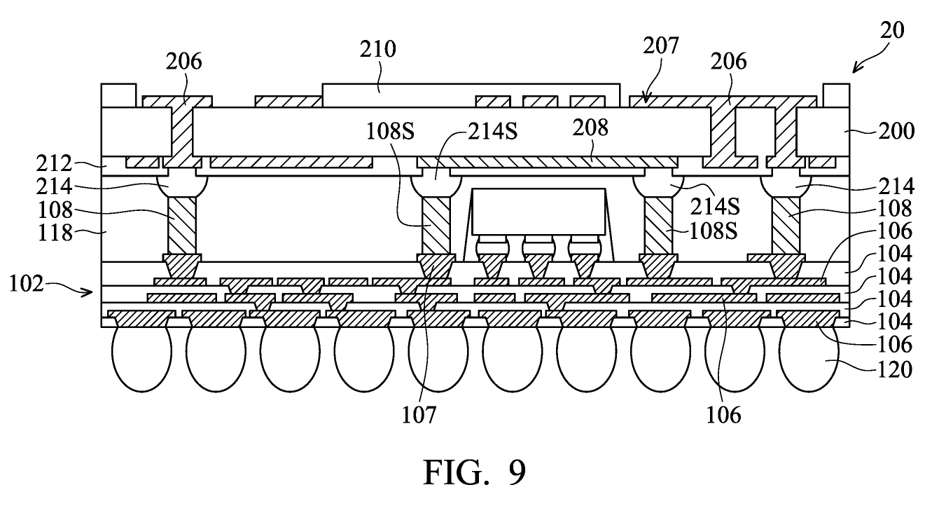

Many variations and/or modifications can be made to embodiments of the disclosure. FIG. 9 is a cross-sectional view of a chip package, in accordance with some embodiments. In some embodiments, the chip package includes a single semiconductor die that is surrounded by the conductive structures 108S and the shielding element 208.

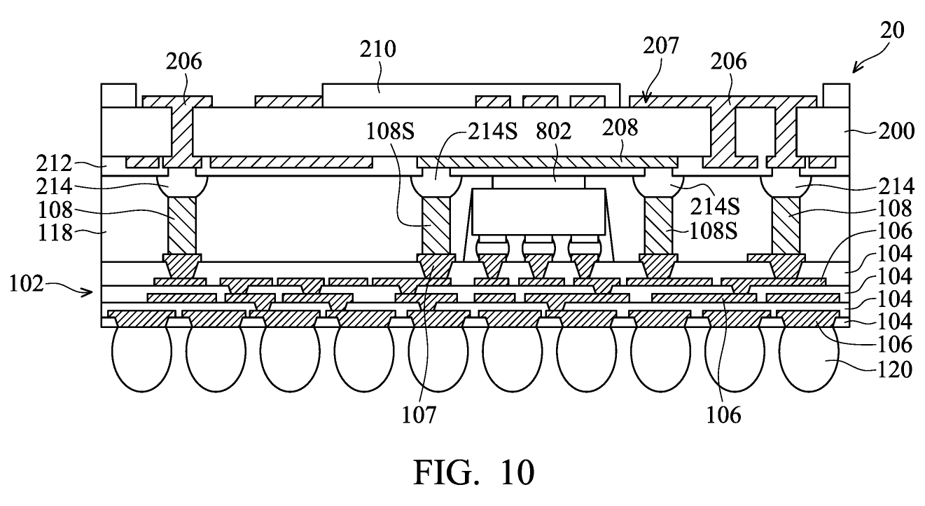

Many variations and/or modifications can be made to embodiments of the disclosure. FIG. 10 is a cross-sectional view of a chip package, in accordance with some embodiments. In some embodiments, the chip package includes a single semiconductor die that is surrounded by the conductive structures 108S and the shielding element 208. As shown in FIG. 10, the adhesive element 802 is formed between the semiconductor die 110A and the shielding element 208.

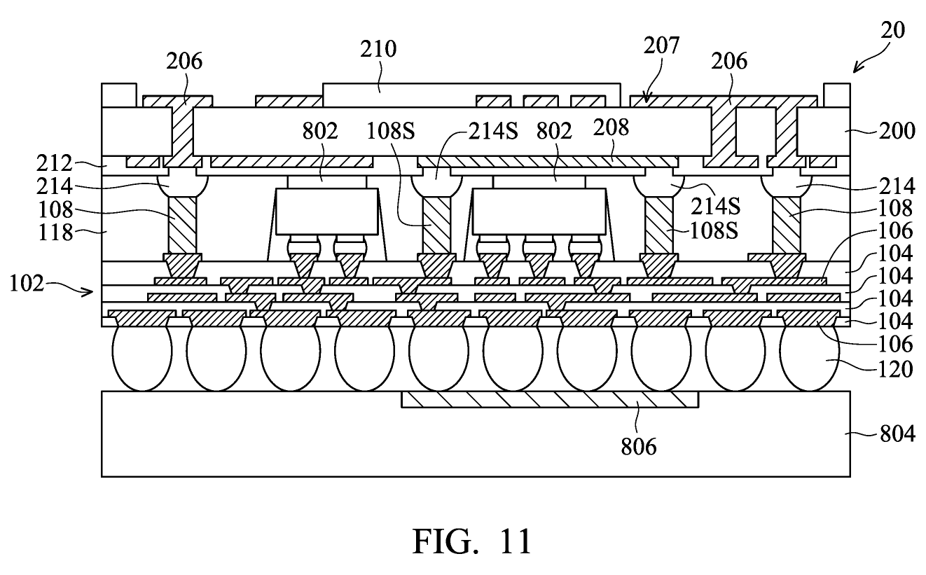

Many variations and/or modifications can be made to embodiments of the disclosure. FIG. 11 is a cross-sectional view of a chip package, in accordance with some embodiments. In some embodiments, a structure the same as or similar to the structure shown in FIG. 8C is provided or formed. Afterwards, the structure is bonded onto a circuit board 804. In some embodiments, the circuit board 804 is a printed circuit board. In some embodiments, the circuit board 804 includes a shielding element 806.

Similar to the shielding element 208, the shielding element 806 may be a conductive plate, a conductive mesh, or a combination thereof. The shielding element 806 may be used to further enhance shielding efficiency. The conductive structures 108S , the shielding element 208, and the shielding element may together be used to prevent the electromagnetic wave generated by the semiconductor die 110A from affecting the operation of nearby device elements, such as the semiconductor die 110B or another nearby package

In some embodiments, the shielding element 208 is formed between the board 200 and the semiconductor die 110A. However, embodiments of the disclosure are not limited thereto. Many variations and/or modifications can be made to embodiments of the disclosure. In some other embodiments, the shielding element is formed at another position.

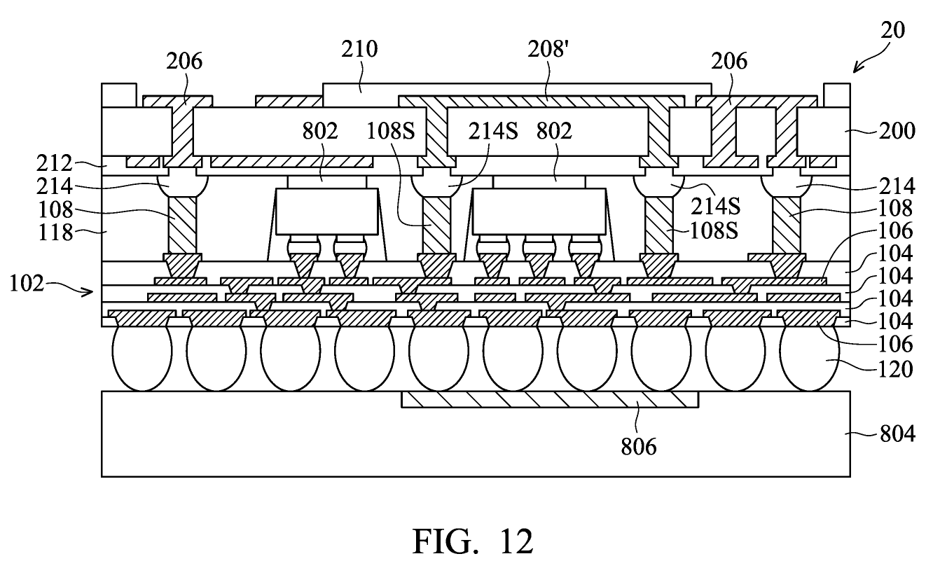

FIG. 12 is a cross-sectional view of a chip package, in accordance with some embodiments. In some embodiments, a shielding element 208’ is formed. The shielding element 208’ has a first portion positioned above the board 200 and a second portion penetrating through the board 200. Therefore, in these cases, the board 200 is positioned between the first portion of the shielding element 208’ and the semiconductor die 110A. The first portion of the shielding element 208’ is electrically connected to the conductive structures 108S through conductive element 214S and the second portion of the shielding element 208’. The material and formation method of the shielding element 208’ may be the same as or similar to those of the shielding element 208 and/or the conductive feature 206. Similar to the shielding element 208, the shielding element 806 may be a conductive plate, a conductive mesh, or a combination thereof.

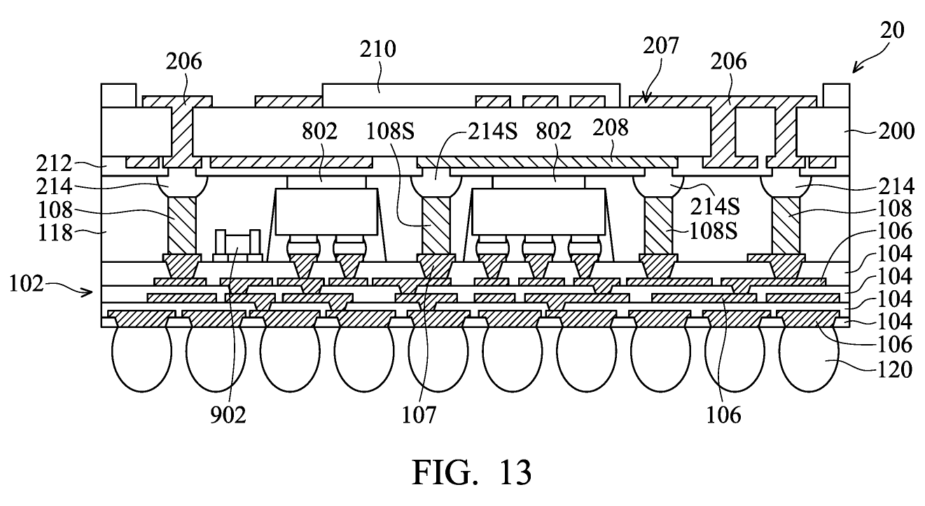

Many variations and/or modifications can be made to embodiments of the disclosure. FIG. 13 is a cross-sectional view of a chip package, in accordance with some embodiments. FIG. 13 shows a cross-sectional view of a chip package that is similar to that shown in FIG. 11. In some embodiments, the chip package further includes one passive component 902. The passive component 902 may include a resistor, a capacitor, an inductor, one or more other suitable elements, or a combination thereof.

Many variations and/or modification can be made to embodiments of the disclosure. For example, the position and/or the number of the antenna element may be modified. In some embodiments, some of the conductive features 106 together function as an antenna element. In some embodiments, some of the conductive structures 108 function as an antenna element. In some embodiments, multiple antenna elements are formed.

Embodiments of the disclosure form a chip package with a shielding structure. One or more conductive structures are formed to surround an area where a semiconductor die is designed to be positioned. The semiconductor die may include radio-frequency circuits and would generate electromagnetic wave during operation. The conductive structures surround the semiconductor die and function as the shielding structure. Therefore, the generated electromagnetic wave may be prevented from negatively affecting the operation of nearby device elements. The quality and performance of the chip package are significantly improved.

According to some embodiments, a method for forming a chip package is provided. The method includes forming a plurality of conductive structures over a carrier substrate. The method also includes disposing a semiconductor die over the carrier substrate such that the conductive structures surround the semiconductor die. The method further includes disposing a shielding element over the semiconductor die and the conductive structures. The shielding element is electrically connected to the conductive structures.

In some embodiments, the method further includes forming a protective layer to surround the conductive structures and the semiconductor die and bonding a protective substrate to the conductive structures before the protective layer is formed. In some embodiments, the method further includes forming the shielding element over the protective substrate before bonding the protective substrate to the conductive structures. In some embodiments, the method further includes forming an antenna element over the protective substrate. In some embodiments, the antenna element is formed over the protective substrate before bonding the protective substrate to the conductive structures. In some embodiments, the protective substrate is bonded to the conductive structures through tin-containing solder elements.

In some embodiments, the method further includes introducing a polymer material between the protective substrate and the carrier substrate and curing the polymer material to form the protective layer. In some embodiments, the method further includes forming a redistribution structure over the carrier substrate before the conductive structures are formed. In some embodiments, the method further includes removing the carrier substrate and forming conductive bumps over the redistribution structure, wherein the redistribution structure is between the protective layer and the conductive bumps. In some embodiments, the method further includes disposing an additional semiconductor die over the carrier substrate before the protective layer is formed, wherein the additional semiconductor die is outside of an area surrounded by the conductive structures. In some embodiments, the shielding element includes a conductive plate, a conductive mesh, or a combination thereof. In some embodiments, two of the conductive structures are separated from each other by a distance, and the distance is smaller than half a wavelength of an electromagnetic wave generated by the semiconductor die.

According to some embodiments, a method for forming a chip package is provided. The method includes forming a plurality of conductive structures over a redistribution structure. The method also includes disposing a semiconductor die over the redistribution structure such that the conductive structures surround the semiconductor die. Two of the conductive structures are separated from each other by a distance, and the distance is smaller than half a wavelength of an electromagnetic wave generated by the semiconductor die.

In some embodiments, each of the conductive structures has a width in a range from about 5 µm to about ten times the distance. In some embodiments, the method further includes forming a protective layer to surround the conductive structures and the semiconductor die and bonding a protective substrate to the conductive structures before the protective layer is formed. In some embodiments, the method further includes forming a shielding element over the protective substrate before bonding the protective substrate to the conductive structures.

According to some embodiments, a method for forming a chip package is provided. The method includes disposing a first semiconductor die and a second semiconductor die over a redistribution structure. The method also includes disposing a plurality of conductive structures over the redistribution structure. The conductive structures surround an area where the first semiconductor die is positioned, and the second semiconductor die is positioned outside of the area.

In some embodiments, two of the conductive structures are separated from each other by a distance, and the distance is smaller than half a wavelength of an electromagnetic wave generated by the first semiconductor die. In some embodiments, the method further includes disposing a shielding element over the first semiconductor die, and the shielding element is electrically connected to the conductive structures. In some embodiments, the shielding element includes a conductive mesh having a plurality of through-holes, and each of the through-holes has a width that is smaller than half the wavelength of the electromagnetic wave generated by the first semiconductor die.

According to some embodiments, a semiconductor package is provided. The semiconductor package includes a redistribution structure, a protective layer, a first semiconductor die, a plurality of conductive structures, a plurality of shielding elements, and a plurality of conductive elements. The protective layer is formed over the redistribution structure. The first semiconductor die is disposed in the protective layer. The conductive structures are formed in the protective layer. The conductive structures at least partially surround the first semiconductor die. The shielding elements at least partially vertically overlap the conductive structures. The conductive elements are in contact with the conductive structures and the shielding elements. Two of the conductive structures are separated from each other by a distance, and the distance is smaller than half a wavelength of an electromagnetic wave generated by the first semiconductor die.

According to some embodiments, a semiconductor package is provided. The semiconductor package includes a redistribution structure, a plurality of conductive bumps, a protective layer, a first semiconductor die, a second semiconductor die, a plurality of conductive structures, a plurality of shielding elements, and a plurality of conductive elements. The conductive bumps are formed under the redistribution structure. The protective layer is formed over the redistribution structure. The first semiconductor die is disposed in the protective layer and electrically connected to the conductive bumps. The second semiconductor die is disposed in the protective layer and electrically connected to the conductive bumps. The conductive structures are formed in the protective layer and between the first semiconductor die and the second semiconductor die. The shielding elements are electrically connected to the conductive bumps. The conductive elements are in contact with the conductive structures and the shielding elements. The conductive structures, the shielding elements, and the conductive elements at least partially vertically overlap each other.

According to some embodiments, a semiconductor package is provided. The semiconductor package includes a redistribution structure, a protective layer, a first semiconductor die, a plurality of conductive structures, a plurality of first shielding elements, a second shielding element, and a plurality of conductive elements. The protective layer is formed over the redistribution structure. The first semiconductor die is disposed in the protective layer. The conductive structures are formed in the protective layer. The conductive structures at least partially surround the first semiconductor die. The first shielding elements at least partially vertically overlap the conductive structures. The second shielding element at least partially vertically overlaps the first semiconductor die. The conductive elements are in contact with the conductive structures and the first shielding elements. The first shielding elements and the second shielding element form an inverted U-shaped structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a redistribution structure;
a protective layer formed over the redistribution structure;
a first semiconductor die disposed in the protective layer;
a plurality of conductive structures formed in the protective layer and at least partially surrounding the first semiconductor die;
a plurality of shielding elements at least partially vertically overlapping the conductive structures; and
a plurality of conductive elements in contact with the conductive structures and the shielding elements,
wherein two of the conductive structures are separated from each other by a distance, and the distance is smaller than half a wavelength of an electromagnetic wave generated by the first semiconductor die.

2. The semiconductor package as claimed in claim 1, further comprising a second semiconductor die disposed in the protective layer.

3. The semiconductor package as claimed in claim 2, wherein at least one of the conductive structures is located between the first semiconductor die and the second semiconductor die.

4. The semiconductor package as claimed in claim 2, wherein the conductive structures surround an area where the first semiconductor die is disposed, and the second semiconductor die is disposed outside of the area.

5. The semiconductor package as claimed in claim 1, wherein the protective layer is in contact with the conductive structures.

6. The semiconductor package as claimed in claim 1, wherein a cross-sectional area of each of the conductive elements is greater than a cross-sectional area of each of the conductive structures.

7. The semiconductor package as claimed in claim 1, wherein the shielding elements at least partially vertically overlap the conductive elements.

8. A semiconductor package, comprising:
a redistribution structure;
a plurality of conductive bumps formed under the redistribution structure;
a protective layer formed over the redistribution structure;
a first semiconductor die disposed in the protective layer and electrically connected to the conductive bumps;
a second semiconductor die disposed in the protective layer and electrically connected to the conductive bumps;
a plurality of conductive structures formed in the protective layer and between the first semiconductor die and the second semiconductor die;
a plurality of shielding elements electrically connected to the conductive bumps; and
a plurality of conductive elements in contact with the conductive structures and the shielding elements,
wherein the conductive structures, the shielding elements, and the conductive elements at least partially vertically overlapping each other.

9. The semiconductor package as claimed in claim 8, further comprising a board formed over the protective layer and in contact with the shielding elements.

10. The semiconductor package as claimed in claim 9, wherein material of the protective layer is different from that of the board.

11. The semiconductor package as claimed in claim 9, wherein a dielectric constant of the protective layer is different from that of the board.

12. The semiconductor package as claimed in claim 9, wherein a dissipation factor constant of the protective layer is different from that of the board.

13. The semiconductor package as claimed in claim 8, wherein the conductive bumps vertically overlap the first semiconductor die and the second semiconductor die.

14. The semiconductor package as claimed in claim 8, wherein two of the conductive structures are separated from each other by a distance, and the distance is smaller than half a wavelength of an electromagnetic wave generated by the first semiconductor die.

15. A semiconductor package, comprising:
a redistribution structure;
a protective layer formed over the redistribution structure;
a first semiconductor die disposed in the protective layer;
a plurality of conductive structures formed in the protective layer and at least partially surrounding the first semiconductor die;
a plurality of first shielding elements at least partially vertically overlapping the conductive structures;
a second shielding element at least partially vertically overlapping the first semiconductor die; and
a plurality of conductive elements in contact with the conductive structures and the first shielding elements,
wherein the first shielding elements and the second shielding element form an inverted U-shaped structure.

16. The semiconductor package as claimed in claim 15, wherein the second shielding element comprises a conductive plate, a conductive mesh, or a combination thereof.

17. The semiconductor package as claimed in claim 15, wherein the second shielding element comprises a conductive mesh having a plurality of through-holes with an equal width.

18. The semiconductor package as claimed in claim 17, wherein the width is smaller than half a wavelength of an electromagnetic wave generated by the first semiconductor die.

19. The semiconductor package as claimed in claim 15, further comprising a second semiconductor die disposed in the protective layer, wherein the second shielding element neither horizontally nor vertically overlaps the second semiconductor die.

20. The semiconductor package as claimed in claim 15, further comprising a board formed over the protective layer, wherein the first shielding elements and the second shielding element surround the board.
